(19) United States
(12) Patent Application Publication
(10) Pub. No.: US 2024/0308785 A1
(43) Pub. Date: Sep. 19, 2024

(54) Transport System

(71) Applicant: Daifuku Co., Ltd., Osaka-shi (JP)

(72) Inventors: Ayaka Kawanami, Hinocho (JP); Yoshitaka Tanaka, Hinocho (JP)

(21) Appl. No.: 18/605,930

(22) Filed: Mar. 15, 2024

(30) Foreign Application Priority Data
Mar. 17, 2023 (JP) 2023-043451

(51) Int. Cl. B65G 49/05; B65G 43/00

(52) U.S. Cl. CPC B65G 49/05; B65G 43/00; B65G 2203/0283

(57) ABSTRACT

A control device holds floor map information regarding a plurality of floors and connection relationship information indicating a connection relationship between different floors connected by a connection route, and controls a transport vehicle on floor routes and the connection route based on the floor map information and the connection relationship information. A management device holds the floor map information regarding the floors in such a manner that a piece of the floor map information can be distinguished for each of the floors, holds the connection relationship information in such a manner that the connection relationship information can be distinguished from the pieces of floor map information corresponding to the floors, and performs update processing for updating the floor map information and the connection relationship information in the control device.

### CROSS-REFERENCE TO RELATED APPLICATION

This application claims priority to Japanese Patent Application No. 2023-043451 filed Mar. 17, 2023, the disclosure of which is hereby incorporated by reference in its entirety.

### BACKGROUND OF THE INVENTION

### 1. Field of the Invention

The present invention relates to a transport system in which an article is transported by a transport vehicle.

### 2. Description of Related Art

An example of the above-mentioned transport system is disclosed in JP 2004-227058A (Patent Document 1). In the following description of the related art, the reference numbers used in Patent Document 1 are shown in parentheses. A transport vehicle system (1), which is a transport system disclosed in Patent Document 1, includes bays (3), transport vehicles (10) that transport articles within the bays (3) and between the bays (3), and area controllers (8) that are provided in correspondence with the bays (3) and each manage the transport vehicles (10) in the corresponding bay (3). Travel routes (2) along which the transport vehicles (10) travel are provided within the bays (3) and between the bays (3), and transport route information, which includes map information regarding all of the travel routes (2), is stored in storage units provided in the area controllers (8). In this transport vehicle system (1), when the layout of a travel route (2) is changed, updated transport route information is transmitted to the area controllers (8), and the transport route information is updated.

In the technology described in Patent Document 1, when the layout of a travel route is changed, updated transport route information that includes map information regarding all of the travel routes is transmitted to a control device that controls the transport vehicles (specifically, the area controllers included in the control device), and the transport route information is updated. Therefore, the amount of information updated in the control device is likely to be large, and the update processing load (e.g., the amount of processing performed by the computation device, and the processing time) is likely to be large. Although not explicitly specified in Patent Document 1, there are cases where the transport system includes a plurality of floors, the floors are each provided with a floor route along which the transport vehicles can move, and connection routes are provided to connect different floors to each other. In this transport system as well, if a configuration is employed in which updated route information that includes information on all of the routes is transmitted to the control device when the layout of a route (e.g., a floor route or a connection route) is changed, the amount of information updated in the control device is likely to be large, and similarly to the transport system of Patent Document 1, the update processing load is likely to be large.

### SUMMARY OF THE INVENTION

In view of the foregoing, in a transport system that includes a plurality of floors and a control device that controls transport vehicles, there is desire for the realization of a technology that can reduce the amount of information updated in the control device when a change is made to the layout of a route.

A transport system according to an aspect of the present disclosure is a transport system in which an article is transported by a transport vehicle, the transport system including: a plurality of floors each having a floor route along which the transport vehicle is configured to travel; a control device configured to control the transport vehicle; and a management device configured to manage data updating performed by the control device, wherein a pair of floors among the plurality of floors are connected to each other by a connection route, the transport vehicle travels between the pair of floors via the connection route, the control device holds floor map information regarding the floor route on each of the floors and connection relationship information regarding a connection relationship between the pair of floors connected by the connection route, and controls the transport vehicle on the floor routes and the connection route based on the floor map information and the connection relationship information, and the management device holds the floor map information regarding the floors in such a manner that a piece of the floor map information can be distinguished for each of the floors, holds the connection relationship information in such a manner that the connection relationship information can be distinguished from the pieces of floor map information corresponding to the floors, and performs update processing for updating the floor map information and the connection relationship information in the control device.

According to this configuration, the control device holds the floor map information regarding the floors and the connection relationship information, and thus can appropriately control the transport vehicle on both the floor routes and the connection route. Also, according to this configuration, the management device, which performs update processing for updating the floor map information and the connection related information in the control device, holds the floor map information regarding the floors in such a manner that a piece of the floor map information can be distinguished for each of the floors, and holds the connection relationship information in such a manner that the connection relationship information can be distinguished from the pieces of floor map information corresponding to the floors. Therefore, when the layout of a route such as a floor route or the connection route is changed, it is possible to update only the information regarding the route related to the layout change in the control device. Therefore, the amount of information that is updated in the control device can be reduced compared with the case where all of the route information (i.e., the floor map information regarding all of the floors and the connection relationship information) needs to be updated in the control device even when only a portion of the layout is changed.

As described above, according to the above configuration, in a transport system that includes a plurality of floors and a control device that controls a transport vehicle, it is possible to reduce the amount of information that is updated in the control device when the layout of a route is changed.

Further features and advantages of the transport system will become clearer from the following description of embodiments given with reference to the drawings.

### BRIEF DESCRIPTION OF THE DRAWINGS

FIG. 1 is a schematic configuration diagram of a transport system.

FIG. 2 is an illustrative diagram of floor routes and connection routes.

FIG. 3 is a block diagram showing a portion of the transport system.

FIG. 4 is an illustrative diagram of creation of update data.

FIG. 5 is an illustrative diagram of update processing.

FIG. 6 is an illustrative diagram of update processing.

### DESCRIPTION OF THE INVENTION

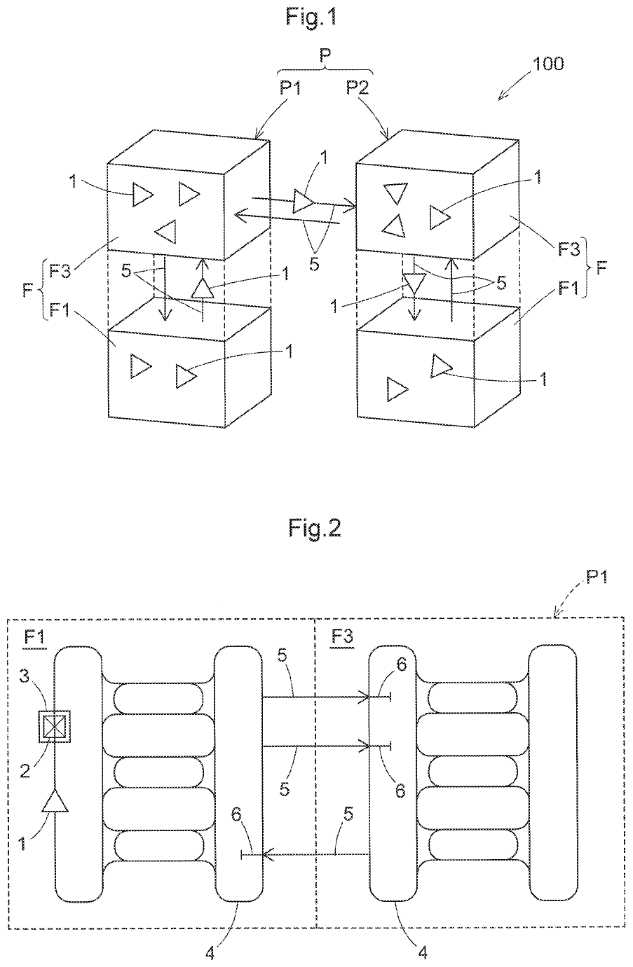

Embodiments of a transport system will be described below with reference to the drawings. As shown in FIG. 1, a transport system 100 is a system in which an article 2 is transported by a transport vehicle 1 (see FIG. 2). The article 2 is, for example, a FOUP (Front Opening Unified Pod) in which a semiconductor wafer is stored.

The transport vehicle 1 transports the article 2 by moving along a movement route. The transport vehicle 1 is an unmanned transport vehicle. The movement route includes floor routes 4 and connection routes 5, which will be described later. Although only one station 3 is shown in FIG. 2, a plurality of stations 3 are set along the movement route (here, the floor route 4). In response to a transport command received from a later-described control device C (a control unit 10 in the present embodiment), the transport vehicle 1 transports the article 2 from a transport source station 3 designated in the transport command to a transport destination station 3 designated in the transport command. Although not shown, each station 3 includes an article support section that supports the article 2, and the article 2 is transferred between the transport vehicle 1 and the article support section at the station 3. The article support section is a load port of a processing device that processes the article 2 (or the item stored in the article 2), an in/out port of a storage device for storing the article 2, or a storage shelf for temporarily storing the article 2, for example.

As shown in FIG. 1, the transport system 100 includes a plurality of floors F. The floors F provided in the transport system 100 include floors F arranged next to each other in the vertical direction, floors F spaced apart in the horizontal direction, or both, for example. In the example shown in FIG. 1, the facility in which the transport system 100 is applied includes two buildings P, namely a first building P1 and a second building P2, and the first building P1 and the second building P2 each include two floors F, namely a first floor F1 and a third floor F3. In both the first building P1 and the second building P2, the first floor F1 and the third floor F3 are adjacent to each other in the vertical direction. Furthermore, the floors F provided in the first building P1 are horizontally spaced apart from the floors F provided in the second building P2.

In the transport system 100, a floor route 4 along which the transport vehicle 1 can move is provided on each of the floors F, and connection routes 5 connect different floors F to each other. The transport vehicle 1 moves between the floors F via the connection routes 5. For example, in the case where the station 3 serving as the article 2 transport source and the station 3 serving as the article 2 transport destination are on different floors F, the transport vehicle 1 moves between the floors F via a connection route 5.

FIG. 2 shows the floor route 4 provided on the first floor F1 of the first building P1, the floor route 4 provided on the third floor F3 of the first building P1, and the connection routes 5 that connect the first floor F1 and the third floor F3 to each other. Note that FIG. 2 shows the routes conceptually, that is to say, two floor routes 4 that are actually adjacent in the vertical direction are shown adjacent in the same plane, and thus actual routes are not necessarily represented accurately. As shown in FIG. 2, when the transport vehicle 1 moves via a connection route 5 to another floor F, the transport vehicle 1 can wait in a standby route 6 on the destination floor F. Situations in which the transport vehicle 1 waits in a standby route 6 will be described later.

The movement routes such as the floor routes 4 and the connection routes 5 may be formed physically or virtually. For example, the floor routes 4 are physically formed by rails. In this case, the rails are suspended from the ceiling, for example. Also, the movement routes such as the floor routes 4 and the connection routes 5 may be a travel route, which is a route along which the transport vehicle 1 moves due to the transport vehicle 1 performing traveling (specifically, rotating a drive wheel), or may be a non-travel route, which is a route along which the transport vehicle 1 moves due to the transport vehicle 1 being transported by another device. For example, the floor routes 4 and the connection routes 5 that connect floors F spaced apart in the horizontal direction (e.g., a building connecting route that connects floors F of different buildings P to each other) are travel routes. Also, the connection routes 5 that connect floors F adjacent in the vertical direction (e.g., a floor connecting route that connects different floors F of the same building P to each other) are non-travel routes, for example. In this case, the non-travel route is a route along which the transport vehicle 1 moves due to the transport vehicle 1 being raised or lowered by a lifting device, for example.

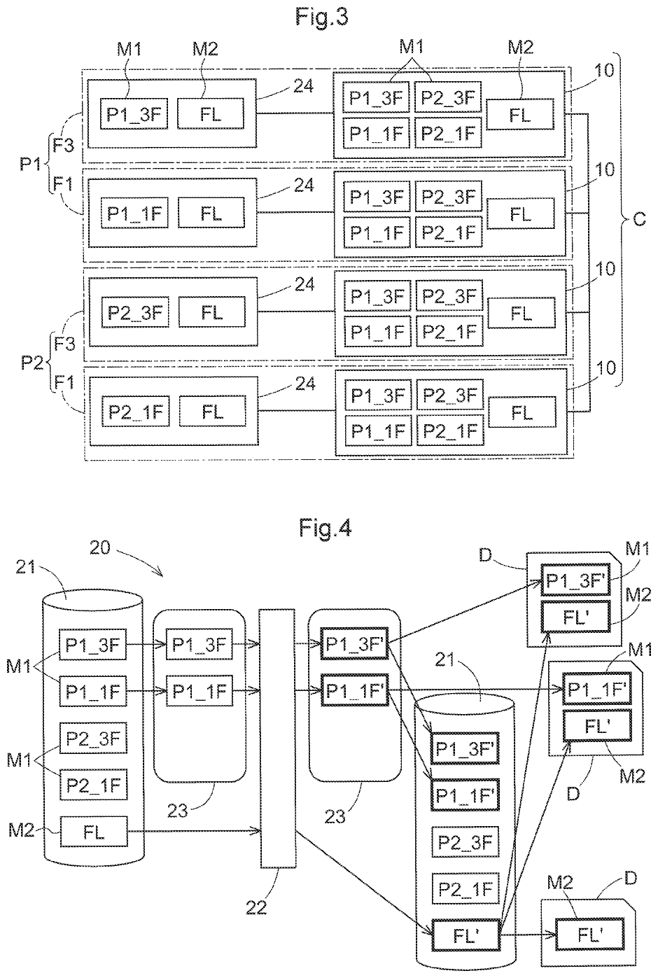

The transport system 100 includes the control device C (see FIG. 3) that controls the transport vehicle 1. In the present embodiment, the control device C includes a plurality of control units 10. The control units 10 are able to communicate with each other. The control device C (in this case, each of the control units 10) includes a computation processing device such as a central processing unit (CPU), and peripheral circuitry such as a memory, and functions of the control device C (here, functions of the control units 10) are realized by cooperation between such hardware and programs (software) executed on hardware such as the computation processing device.

The floors F are each managed by one or more of the control units 10. Each of the control units 10 manages the transport vehicle 1 (e.g., controls the movement of the transport vehicle 1) on the one or more floors F that the control unit 10 manages. In the present embodiment, the transport system 100 includes the same number of control units 10 as floors F. Each of the floors F is managed by one control unit 10, and each of the control units 10 manages one floor F. FIG. 3 shows four control units 10 corresponding to the four floors F shown in FIG. 1. In FIG. 3, each of the floors F (F1, F3) is represented by a dashed-dotted rectangle, and each of the floors F is managed by the control unit 10 surrounded by the corresponding rectangle. For example, the control unit 10 at the top in FIG. 3 is the control unit 10 that manages the third floor F3 of the first building P1.

Each of the control units 10 can determine at least the current position of the transport vehicle 1 on the floor F managed by that control unit 10. In the present embodiment, the transport vehicle 1 can recognize its own current position, and the control unit 10 can determine the current position of the transport vehicle 1 by acquiring information indicating the current position of the transport vehicle 1 from the transport vehicle 1.

The control device C holds floor map information M1 corresponding to each of the floors F (in other words, floor map information M1 corresponding to all of the floors F). In the present embodiment, each of the control units 10 holds at least floor map information M1 corresponding to the floor F managed by the control unit 10, and the control device C that includes the control units holds floor map information M1 corresponding to all of the floors F. The floor map information M1 is information regarding a floor route 4 (e.g., map information indicating the shape of the route). For example, the floor map information M1 corresponding to the first floor F1 of the first building P1 is information regarding the floor route 4 provided on the first floor F1 of the first building P1. In the present embodiment, in addition to information regarding the floor route 4, the floor map information M1 also includes information regarding the station 3 provided along the floor route 4.

In the present embodiment, each of the control units 10 holds floor map information M1 corresponding to all of the floors F. In the example shown in FIG. 3, each of the four control units 10 holds pieces of floor map information M1 corresponding to four floors F. In FIG. 3 and later-referenced FIGS. 4 to 6, “P1_1F” denotes the floor map information M1 corresponding to the first floor F1 of the first building P1, “P1_3F” denotes the floor map information M1 corresponding to the third floor F3 of the first building P1, “P2_1F” denotes the floor map information M1 corresponding to the first floor F1 of the second building P2, and “P2_3F” denotes the floor map information M1 corresponding to the third floor F3 of the second building P2. Furthermore, in FIGS. 3 to 6, “FL” denotes connection relationship information M2 described below. Hereinafter, there are cases where the floor map information M1 corresponding to an N-th floor FN of an M-th building PM (Mis 1 or 2, N is 1 or 3) is described as floor map information M1[PM_NF]. Also, there are cases where the connection relationship information M2 is described as connection relationship information M2[FL].

The control device C holds the connection relationship information M2. In the present embodiment, each of the control units 10 holds the connection relationship information M2. The connection relationship information M2 is information indicating connection relationships between different floors F connected by the connection routes 5. Whereas the pieces of floor map information M1 each correspond to one floor F, the connection relationship information M2 includes information regarding all of the connection relationships between different floors F connected by the connection routes 5. The two floors F that are connected by a connection route 5 cannot be specified by referring only to information regarding the connection route 5 (e.g., map information such as the shape of the route), but it is possible to specify the two floors F that are connected by a connection route 5 by referring to the connection relationship information M2. For example, when the transport vehicle 1 moves to another floor F via a connection route 5, the piece of floor map information M1 used to control the transport vehicle 1 is switched to the piece of floor map information M1 corresponding to the destination floor F, and by referring to the connection relationship information M2, it is possible to determine which piece of floor map information M1 corresponds to the destination floor F.

In the present embodiment, information regarding a connection route 5 is included in the floor map information M1. Specifically, in addition to information regarding a floor route 4, the floor map information M1 also includes information regarding a connection route 5 connected to the floor route 4. For example, information regarding the connection route 5 that connects the first floor F1 and the third floor F3 of the first building P1 shown in FIG. 2 is included in the floor map information M1 corresponding to the first floor F1 and the floor map information M1 corresponding to the third floor F3. However, the floor map information M1 corresponding to the first floor F1 does not include information indicating that the destination of the connection route 5 is the third floor F3, and the floor map information M1 corresponding to the third floor F3 does not include information indicating that the destination of the connection route 5 is the first floor F1. Therefore, for example, when the transport vehicle 1 moves from the first floor F1 to the third floor F3 via the connection route 5, by referring to the connection relationship information M2, it can be determined that there is a switch from the piece of floor map information M1 corresponding to the first floor F1 to the piece of floor map information M1 corresponding to the third floor F3.

Note that when the transport vehicle 1 moves to another floor F via a connection route 5, there may be situations where the piece of floor map information M1 used for controlling the transport vehicle 1 cannot be switched to the latest piece of floor map information M1 corresponding to the destination floor F. For example, such a situation can occur if there is a delay in updating of the floor map information M1 in the control unit 10 that manages the destination floor F, or if the communication situation is poor and the transport vehicle 1 cannot acquire the latest floor map information M1 from the control unit 10 that manages the destination floor F. In the present embodiment, when such a situation occurs, the transport vehicle 1 is caused to move to a standby route 6 included in the floor route 4 of the destination floor F. In the present embodiment, the connection relationship information M2 includes information necessary for moving from a connection route 5 to a standby route 6, such as information that associates connection routes 5 and standby routes 6 with each other, for example.

The control device C controls the transport vehicle 1 on the floor route 4 and the connection route 5 based on the floor map information M1 and the connection relationship information M2. In the present embodiment, based on the floor map information M1 and the connection relationship information M2, each of the control units 10 controls the transport vehicle 1 on the floor route 4 of the corresponding floor F and on the connection routes 5 connected to the corresponding floor F. When the transport vehicle 1 moves between two floors F that are managed by different control units via a connection route 5, the control unit 10 that controls the transport vehicle 1 is switched from the control unit 10 that manages the origin floor F to the control unit 10 that manages the destination floor F.

In the present embodiment, the floor map information M1 and the connection relationship information M2 are transmitted from the control device C (specifically, a control unit 10, which similarly applies hereinafter in this paragraph) to the transport vehicle 1, and, in response to a command (e.g., a transport command) from the control device C, the transport vehicle 1 moves along a floor route 4 or a connection route 5 based on the current position, the floor map information M1, and the connection relationship information M2. Note that if the route that the transport vehicle 1 moves along includes a route along which the transport vehicle 1 moves due to the transport vehicle 1 being transported by another device (above-described non-travel route), the control of the transport vehicle 1 by the control device C also includes controlling the transport vehicle 1 via the other device.

In this way, the floor map information M1 and the connection relationship information M2 held by the control device C (specifically, the control unit 10) are used to control the transport vehicle 1, and therefore if the layout of a movement route (e.g., a floor route 4 or a connection route 5) of the transport vehicle 1 is changed, it is necessary to update the floor map information M1 and the connection relationship information M2. Updating of the floor map information M1 and the connection relationship information M2 will be described below.

The transport system 100 includes a management device 20 (see FIG. 4) that manages the updating of data in the control device C (in the present embodiment, the control units 10). The management device 20 holds the floor map information M1 regarding the floors F in such a manner that a piece of the floor map information M1 can be distinguished for each of the floors F, and also holds the connection relationship information M2 in such a manner that the connection relationship information M2 can be distinguished from the pieces of floor map information M1 corresponding to the floors F. In other words, the management device 20 holds the floor map information M1 regarding the floors F in such a manner that the floor map information M1 is separable for each of the floors F, and also holds the connection relationship information M2 in such a manner that the connection relationship information M2 is separable from floor map information M1 corresponding to the floors F. In the example shown in FIG. 4, the management device 20 stores floor map information M1 corresponding to the first floor F1 of the first building P1, floor map information M1 corresponding to the third floor F3 of the first building P1, floor map information M1 corresponding to the first floor F1 of the second building P2, floor map information M1 corresponding to the third floor F3 of the second building P2, and the connection relationship information M2 in such a manner that such pieces of information can be distinguished from each other.

The management device 20 performs update processing for updating the floor map information M1 and the connection relationship information M2 in the control device C (in the present embodiment, the control units 10). The update processing for updating information such as the floor map information M1 and the connection relationship information M2 in the control device C (specifically, the control units 10, which similarly applies hereinafter in this paragraph) is performed by installing new information reflecting a layout change (specifically, information included in later-described update data D) in the control device C. By installing new information in the control device C, the information stored in the control device C is overwritten with the new information.

When a change is made to a floor route 4, the management device 20 updates only the piece of floor map information M1 corresponding to the floor F where the changed floor route 4 is provided. The floor map information M1 is updated in at least the control unit 10 that manages the floor F where the changed floor route 4 is provided. In the present embodiment, each of the control units holds the floor map information M1 corresponding to all of the floors F. Therefore, the floor map information M1 is updated in all of the control units 10.

When a change is made to a connection route 5 (e.g., addition or deletion of a connection route 5), the connection relationship information M2 is updated, and furthermore the pieces of floor map information M1 corresponding to the floors F connected to that connection route 5 are updated. For example, when a connection route 5 is added, information regarding connection points between that connection route 5 and floor routes 4 connected thereto is added to the floor map information M1 corresponding to the floors F connected to the connection route 5, and when a connection route 5 is deleted, information regarding connection points between that connection route 5 and the floor routes 4 that were connected thereto is deleted from the floor map information M1 corresponding to the floors F that were connected to the connection route 5. In the present embodiment, information regarding the connection routes 5 is included in the floor map information M1. Therefore, when a connection route 5 is added, information regarding the connection points between that connection route 5 and the floor routes 4 connected thereto as well as information regarding the connection route 5 is added to the floor map information M1 corresponding to the floors F connected to the connection route 5. Also, when a connection route 5 is deleted, information regarding the connection points between that connection route 5 and the floor routes 4 that were connected thereto as well as information regarding the connection route 5 is deleted from the floor map information M1 corresponding to the floors F that were connected to the connection route 5.

In view of the above, when a change is made to a connection route 5, the management device 20 updates the connection relationship information M2 and the floor map information M1 corresponding to the floors F connected to the changed connection route 5. For example, if a change is made to a connection route 5 shown in FIG. 2, the floors F that are connected to the changed connection route 5 are the first floor F1 of the first building P1 and the third floor F3 of the first building P1. Therefore, the management device 20 updates the connection relationship information M2, the floor map information M1 corresponding to the first floor F1 of the first building P1, and the floor map information M1 corresponding to the third floor F3 of the first building P1. The connection relationship information M2 is updated in all of the control units 10. On the other hand, the floor map information M1 is updated in at least the control units 10 that manage the floors F connected to the changed connection route 5. In the present embodiment, each of the control units 10 holds the floor map information M1 corresponding to all of the floors F. Therefore, the floor map information M1 is updated in all of the control units 10.

As shown in FIG. 4, in the present embodiment, the management device 20 includes a database 21 that stores the latest floor map information M1 and the latest connection relationship information M2, and an update data creation unit 22 that creates update data D to be transmitted to the control device C (in the present embodiment, the control units 10). In the present embodiment, the management device 20 uses a version management system to manage the floor map information M1 and the connection relationship information M2 stored in the database 21. The functions of the update data creation unit 22 and a below-described update processing unit 24 are realized through cooperation between hardware such as a computation processing device and a program (software) executed on the hardware.

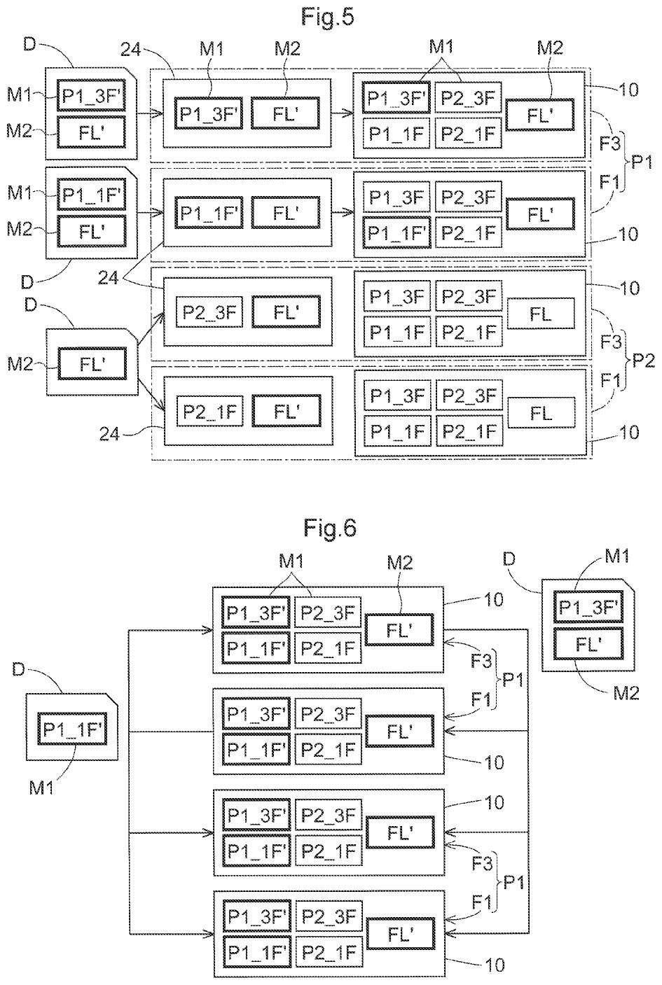

In the present embodiment, the management device 20 includes update processing units 24 (see FIGS. 3 and 5) that install information included in the update data D in the control device C (specifically, the control units 10). Here, an update processing unit 24 is provided for each of the control units 10, and the update processing units 24 are each able to communicate with the corresponding control unit 10. Each of the update processing units 24 holds the latest connection relationship information M2 and the latest piece of floor map information M1 corresponding to the floor F that is managed by the corresponding control unit 10. In FIGS. 3 and 5, in order to make it easier to understand the correspondence between the control units 10 and the update processing units 24, a control unit 10 and an update processing unit 24 provided for that control unit 10 are surrounded by the dashed-dotted rectangle that represents the floor F managed by that control unit 10. Note that a configuration is possible in which the control unit 10 includes the functions of the update processing unit 24.

Although not described in detail, in the present embodiment, when a change is made to station information (e.g., when a station 3 is added) corresponding to a floor F managed by a control unit 10, the corresponding update processing unit 24 can cause the change in the station information to be reflected in the floor map information M1. The floor map information M1 reflecting the change in the station information is installed in the corresponding control unit 10 by the update processing unit 24, and then transmitted from that control unit 10 to the other control units 10.

When a change is made to a floor route 4, the update data creation unit 22 reads the latest piece of floor map information M1 corresponding to the floor F where the changed floor route 4 is provided from the database 21, and causes the change in the floor route 4 to be reflected in the floor map information M1 to obtain new floor map information M1. The update data creation unit 22 then creates update data D that includes the new floor map information M1. Update processing for updating the floor map information M1 in the control device C (specifically, the corresponding control unit 10) is performed by the above-described update data D being installed in the control device C (specifically, in the present embodiment, being installed in the corresponding control unit via the corresponding update processing unit 24).

When a change is made to a connection route 5, the update data creation unit 22 reads the latest floor map information M1 for the floors F connected to the changed connection route 5 and the latest connection relationship information M2 from the database 21, and causes the change in the connection route 5 to be reflected in the floor map information M1 and the connection relationship information M2 to obtain new floor map information M1 and new connection relationship information M2. The update data creation unit 22 then creates update data D that is a combination of the new floor map information M1 and the new connection relationship information M2 (in other words, update data D that includes the new floor map information M1 and the new connection relationship information M2). Update processing for updating the floor map information M1 and the connection relationship information M2 in the control device C (specifically, the corresponding control unit 10) is performed by the above-described update data D being installed in the control device C (specifically, in the present embodiment, being installed in the corresponding control unit via the corresponding update processing unit 24).

The creation of the update data D will be specifically described below with reference to FIG. 4. Also, in FIGS. 4 to 6, “PM_NF”′ (M is 1 or 2, N is 1 or 3) denotes new floor map information M1 (hereinafter sometimes referred to as floor map information M1[PM_NF′]) obtained by reflecting a layout change in floor map information M1[PM_NF]. Also, “FL”′ denotes new connection relationship information M2 (hereinafter sometimes referred to as connection relationship information M2[FL′]) obtained by reflecting a layout change in connection relationship information M2[FL].

FIG. 4 envisions the case where a change is made to a connection route 5 that connects the first floor F1 of the first building P1 to the third floor F3 of the first building P1. In this case, the update data creation unit 22 reads, from the database 21, the latest floor map information M1[P1_1F] and the latest floor map information M1[P1_3F], which are the pieces of floor map information M1 corresponding to the floors F connected to the changed connection route 5, and loads the read information to a workspace 23. The update data creation unit 22 then reflects the change in the connection route 5 in the floor map information M1[P1_1F] and the floor map information M1[P1_3F] that were loaded to the workspace 23, to obtain floor map information M1[P1_1F′] and floor map information M1[P1_3F′]. The update data creation unit 22 stores the floor map information M1[P1_1F′] and the floor map information M1[P1_3F′] in the database 21. As a result, the change in the floor map information M1 is reflected in the database 21.

Additionally, the update data creation unit 22 reads the latest connection relationship information M2[FL] from the database 21. The update data creation unit 22 then reflects the change in the connection route 5 in the connection relationship information M2[FL] to obtain connection relationship information M2[FL′]. The update data creation unit 22 stores the connection relationship information M2[FL′] in the database 21. The change in the connection relationship information M2 is thus reflected in the database 21.

The update data creation unit 22 then creates update data D by combining the floor map information M1[P1_1F′] in the workspace 23 and the connection relationship information M2[FL′] stored in the database 21, and also creates update data D by combining the floor map information M1[P1_3F′] in the workspace 23 and the connection relationship information M2[FL′] stored in the database 21. In the present embodiment, the update data creation unit 22 also creates update data D that includes only the connection relationship information M2[FL′].

Here, when a change is made to a floor route 4, the floor F where the changed floor route 4 is provided will be called the “first target floor”, and when a change is made to a connection route 5, the floors F connected to the changed connection route 5 will be called “second target floors”. In the present embodiment, when a change is made to a floor route 4, the management device 20 prioritizes updating (in other words, preferentially updates) the floor map information M1 corresponding to the first target floor in the control unit 10 that manages the first target floor over updating the floor map information M1 corresponding to the first target floor in the other control units 10. Also, in the present embodiment, when a change is made to a connection route 5, the management device 20 prioritizes updating (in other words, preferentially updates) the floor map information M1 corresponding to the second target floors in the control units 10 that manage the second target floors over updating the floor map information M1 corresponding to the second target floors in the other control units 10. Note that when a change is made to a connection route 5, the management device 20 also prioritizes updating (in other words, preferentially updates) the connection relationship information M2 in the control units 10 that manage the second target floors over updating the connection relationship information M2 in the other control units 10.

In the present embodiment, when a change is made to a target floor (the first target floor or a second target floor, which similarly applies hereinafter) and update processing is performed for the floor map information M1 (when a change is made to a connection route 5, the floor map information M1 and the connection relationship information M2, which similarly applies hereinafter in this paragraph) corresponding to the target floor, the management device 20 performs such update processing in accordance with the above-described priority order by first updating the floor map information M1 corresponding to the target floor in the control unit that manages the target floor, and then updating the floor map information M1 corresponding to the target floor in the other control units 10. Specifically, when a change is made to a floor route 4, the management device 20 updates the floor map information M1 in a first target control unit, which is the control unit 10 that manages the first target floor, then causes the updated floor map information M1 to be transmitted from the first target control unit to first non-target control units, which are the other control units 10, and then updates the floor map information M1 in the first non-target control units. Also, when a change is made to a connection route 5, the management device 20 updates the floor map information M1 in second target control units, which are the control units 10 that manage the second target floors, then causes the updated floor map information M1 to be transmitted from at least one of the second target control units to second non-target control units, which are the other control units 10, and then updates the floor map information M1 in the second non-target control units. Note that the transmission of the updated floor map information M1 from the first target control unit and the second target control units to the other control units 10 is performed under control of the management device 20.

The update processing performed by the management device 20 will be specifically described below with reference to FIGS. 5 and 6. FIGS. 5 and 6 envision the case where a change is made to a connection route 5 that connects the first floor F1 of the first building P1 and the third floor F3 of the first building P1, and update processing is performed using the update data D shown in FIG. 4. Therefore, here, the first floor F1 of the first building P1 and the third floor F3 of the first building P1 are the above-mentioned “second target floors”, and the updating of the floor map information M1 and the connection relationship information M2 in the control unit 10 that manages the first floor F1 of the first building P1 and in the control unit 10 that manages the third floor F3 of the first building P1 is prioritized over the updating of the floor map information M1 and the connection relationship information M2 in the control unit 10 that manages the first floor F1 of the second building P2 and in the control unit 10 that manages the third floor F3 of the second building P2.

Specifically, as shown in FIG. 5, the update processing unit 24 provided for the control unit that manages the first floor F1 of the first building P1 acquires update data D that includes the floor map information M1[P1_1F′] and the connection relationship information M2[FL′], and updates the floor map information M1 and the connection relationship information M2 held by the update processing unit 24. The update processing unit 24 then installs the updated floor map information M1[P1_1F′] and the updated connection relationship information M2[FL′] in the control unit 10 that manages the first floor F1 of the first building P1. As a result, the floor map information M1 and the connection relationship information M2 are updated in the control unit 10 that manages the first floor F1 of the first building P1.

Also, as shown in FIG. 5, the update processing unit 24 provided for the control unit 10 that manages the third floor F3 of the first building P1 acquires update data D that includes the floor map information M1[P1_3F′] and the connection relationship information M2[FL′], and updates the floor map information M1 and the connection relationship information M2 held by the update processing unit 24. The update processing unit 24 then installs the updated floor map information M1[P1_3F′] and the updated connection relationship information M2[FL′] in the control unit 10 that manages the third floor F3 of the first building P1. As a result, the floor map information M1 and the connection relationship information M2 are updated in the control unit 10 that manages the third floor F3 of the first building P1.

As described above, in the present embodiment, each of the update processing units 24 holds the latest piece of floor map information M1 corresponding to the floor F that is managed by the corresponding control unit 10 and the latest connection relationship information M2. Therefore, as shown in FIG. 5, the update processing unit 24 provided for the second non-target control unit (here, the update processing unit 24 provided for the control unit 10 that manages the first floor F1 of the second building P2, and the update processing unit 24 provided for the control unit 10 that manages the third floor F3 of the second building P2), acquires update data D that includes the connection relationship information M2[FL′] (here, update data D that includes only the connection relationship information M2[FL′]), and updates the connection relationship information M2 held by the update processing unit 24.

The floor map information M1 and the connection relationship information M2 are first updated in the control unit 10 that manages the first floor F1 of the first building P1 and the control unit 10 that manages the third floor F3 of the first building P1, and then the floor map information M1 and the connection relationship information M2 are updated in the control unit 10 that manages the first floor F1 of the second building P2 and in the control unit 10 that manages the third floor F3 of the second building P2.

Specifically, as shown in FIG. 6, in the case where the first floor F1 of the first building P1 is a “second target floor”, the control unit 10 that manages the first floor F1 of the first building P1 transmits update data D that includes the floor map information M1[P1_1F′] to the control unit 10 that manages the third floor F3 of the first building P1, the control unit 10 that manages the first floor F1 of the second building P2, and the control unit 10 that manages the third floor F3 of the second building P2, which are second non-target control units in this case. As a result, the floor map information M1 corresponding to the first floor F1 of the first building P1 is updated in the second non-target control units. Also, in the case where the third floor F3 of the first building P1 is a “second target floor”, the control unit 10 that manages the third floor F3 of the first building P1 transmits update data D that includes the floor map information M1[P1_3F′] to the control unit 10 that manages the first floor F1 of the first building P1, the control unit 10 that manages the first floor F1 of the second building P2, and the control unit 10 that manages the third floor F3 of the second building P2, which are second non-target control units in this case. As a result, the floor map information M1 corresponding to the third floor F3 of the first building P1 is updated in the second non-target control units.

In the present embodiment, the updated connection relationship information M2[FL′] is also transmitted from the control units 10 that manage the second target floors to the other control units 10, and the connection relationship information M2 is updated in the other control units 10, but the same version of the connection relationship information M2[FL′] does not need to be transmitted from more than one control unit 10. Therefore, in the example shown in FIG. 6, the updated connection relationship information M2[FL′] is included in the update data D transmitted from the control unit 10 that manages the third floor F3 of the first building P1, but the updated connection relationship information M2[FL′] is not included in the update data D transmitted from the control unit 10 that manages the first floor F1 of the first building P1. Also, although not shown, the updated connection relationship information M2[FL′] is installed in the control unit 10 that manages the first floor F1 of the first building P1 by the corresponding update processing unit 24, and therefore the updated connection relationship information M2[FL′] does not need to be included in the update data D transmitted from the control unit 10 that manages the third floor F3 of the first building P1 to the control unit 10 that manages the first floor F1 of the first building P1.

Note that depending on the configuration of the transport system 100, when an update processing unit 24 performs update processing on the corresponding control unit 10 through installation processing, the control of the transport vehicle 1 by that control unit 10 may be interrupted. Regarding this point, in the present embodiment, the control units 10 on which update processing is performed by corresponding update processing units 24 can be limited to the control units 10 that manage the target floors (in the example shown in FIG. 5, two control units 10). Therefore, even if the above-mentioned interruption is performed, it is possible to suppress the influence on the article 2 transport efficiency in the system as a whole.

### OTHER EMBODIMENTS

(1) In the above embodiment, an example is described in which the management device 20 updates the floor map information M1 in a target control unit (the first target control unit or a second target control unit, which similarly applies hereinafter in this paragraph), then causes the updated floor map information M1 (specifically, update data D that includes the updated floor map information M1) to be transmitted from the target control unit to a non-target control unit (the first non-target control unit or the second non-target control unit, which similarly applies hereinafter in this paragraph), and then updates the floor map information M1 in the non-target control unit. However, the present disclosure is not limited to such a configuration, and a configuration is possible in which the updated floor map information M1 is installed in the non-target control unit by a method different from transmission from the target control unit (e.g., installation processing performed by the corresponding update processing unit 24).

(2) In the above embodiment, an example is described in which when a change is made to a target floor (the first target floor or a second target floor, which similarly applies hereinafter in this paragraph), the management device 20 prioritizes updating the floor map information M1 corresponding to the target floor in the control unit 10 that manages the target floor over updating the floor map information M1 corresponding to the target floor in the other control units 10. However, the present disclosure is not limited to such a configuration, and for example, a configuration is possible in which the management device 20 updates the floor map information M1 in all of the control units 10 at the same time.

(3) In the above embodiment, an example is described in which each of the control units 10 holds the floor map information M1 corresponding to all of the floors F. However, the present disclosure is not limited to such a configuration, and for example, a configuration is possible in which each of the control units 10 holds only the piece of floor map information M1 corresponding to the floor F managed by the control unit 10. In this case, the floor map information M1 is updated in only the control unit 10 that manages the floor F where the changed floor route 4 is provided.

(4) In the above embodiment, an example is described in which the floors F are each managed by one control unit 10. However, the present disclosure is not limited to such a configuration, and a configuration is possible in which one or more of the floors F is managed by a plurality of control units 10. In this case, for example, a configuration is possible in which the control units 10 that manage the same floor F manage mutually different regions of the floor F. Also, a configuration is possible in which a priority order is set for the control units 10 that manage the same floor F, the control unit 10 with the highest priority basically manages the floor F, and if an abnormality such as a failure occurs in the control unit 10 with the highest priority, a control unit 10 with a lower priority manages the floor F.

(5) In the above embodiment, an example is described in which each of the control units 10 manages one floor F. However, the present disclosure is not limited to such a configuration, and a configuration is possible in which one or more of the control units 10 manages a plurality of floors F.

(6) In the above embodiment, an example is described in which the control device C includes a plurality of control units 10. However, the present disclosure is not limited to such a configuration, and a configuration is possible in which the control device C includes only one control unit 10. In this case, the control device C (specifically, the one control unit 10 included in the control device C) performs management for all of the floors F, and manages the transport vehicles 1 on all of the floors F.

(7) It should be noted that the configurations disclosed in each of the above-described embodiments can also be applied in combination with configurations disclosed in other embodiments (including combinations between embodiments described as other embodiments) as long as no contradiction arises. Regarding such other configurations as well, the embodiments disclosed in this specification are merely examples in all respects. Therefore, various modifications can be made as appropriate without departing from the spirit of the present disclosure.

### Overview of Embodiments

The following is a description of aspects of the transport system described above.

A transport system according to an aspect is a transport system in which an article is transported by a transport vehicle, the transport system including: a plurality of floors each having a floor route along which the transport vehicle is configured to travel; a control device configured to control the transport vehicle; and a management device configured to manage data updating performed by the control device, wherein a pair of floors among the plurality of floors are connected to each other by a connection route, the transport vehicle travels between the pair of floors via the connection route, the control device holds floor map information regarding the floor route on each of the floors and connection relationship information regarding a connection relationship between the pair of floors connected by the connection route, and controls the transport vehicle on the floor routes and the connection route based on the floor map information and the connection relationship information, and the management device holds the floor map information regarding the floors in such a manner that a piece of the floor map information can be distinguished for each of the floors, holds the connection relationship information in such a manner that the connection relationship information can be distinguished from the pieces of floor map information corresponding to the floors, and performs update processing for updating the floor map information and the connection relationship information in the control device.

According to this configuration, the control device holds the floor map information regarding the floors and the connection relationship information, and thus can appropriately control the transport vehicle on both the floor routes and the connection route. Also, according to this configuration, the management device, which performs update processing for updating the floor map information and the connection related information in the control device, holds the floor map information regarding the floors in such a manner that a piece of the floor map information can be distinguished for each of the floors, and holds the connection relationship information in such a manner that the connection relationship information can be distinguished from the pieces of floor map information corresponding to the floors. Therefore, when the layout of a route such as a floor route or the connection route is changed, it is possible to update only the information regarding the route related to the layout change in the control device. Therefore, the amount of information that is updated in the control device can be reduced compared with the case where all of the route information (i.e., the floor map information regarding all of the floors and the connection relationship information) needs to be updated in the control device even when only a portion of the layout is changed.

As described above, according to the above configuration, in a transport system that includes a plurality of floors and a control device that controls a transport vehicle, it is possible to reduce the amount of information that is updated in the control device when the layout of a route is changed.

Here, it is preferable that in response to a change in a floor route among the plurality of floor routes, the management device updates only the piece of floor map information corresponding to the floor where the changed floor route is provided, and in response to a change in the connection route, the management device updates the connection relationship information and the pieces of floor map information corresponding to the floors connected to the changed connection route.

According to this configuration, when the layout of a route such as a floor route or the connection route is changed, the information targeted for update processing can be appropriately narrowed down in accordance with the content of the layout change. Therefore, it is possible to reduce the amount of information updated in the control device while also appropriately performing update processing.

In the above configuration, it is preferable that the management device includes: a database configured to have stored therein latest floor map information and latest connection relationship information; and an update data creation unit configured to create update data to be transmitted to the control device, and in response to a change in the connection route, the update data creation unit reads, from the database, the connection relationship information and the pieces of floor map information corresponding to the floors connected to the changed connection route, and creates the update data in which new floor map information and new connection relationship information are included.

According to this configuration, when a change is made to the connection route, the latest floor map information and the latest connection relationship information are read from the database, and it is possible to appropriately create update data for updating the connection relationship information and the pieces of floor map information that correspond to the floors connected to the changed connection route. Furthermore, according to the above configuration, the latest connection relationship information can be stored in the database in such a manner that the latest connection relationship information can be distinguished from the latest floor map information, and therefore if a change is made to the connection route, update data that includes only new connection relationship information can also be easily created separately from update data that includes both new floor map information and new connection relationship information.

Also, it is preferable that the control device includes a plurality of control units, each of the floors is managed by one or more of the control units, each of the control units holds the pieces of floor map information corresponding to all of the floors and manages the transport vehicle on each floor managed by the control unit, in response to a change in a floor route among the plurality of floor routes, the management device prioritizes updating the piece of floor map information corresponding to a first target floor, which is the floor where the changed floor route is provided, in the control unit that manages the first target floor over updating the piece of floor map information corresponding to the first target floor in another one of the control units, and in response to a change in the connection route, the management device prioritizes updating the pieces of floor map information corresponding to second target floors, which are the floors connected to the changed connection route, in the control units that manage the second target floors over updating the pieces of floor map information corresponding to the second target floors in another one of the control units.

According to this configuration, in the case where the control device includes a plurality of control units, updated floor map information can be quickly applied to the management of the transport vehicle (e.g., control for causing the transport vehicle to move) on the target floor (the first target floor or a second target floor, which similarly applies hereinafter in this paragraph). Note that on a non-target floor, which is a floor other than the target floor, there is no change in the floor route, and thus there is not a high degree of urgency in performing update processing on the control unit that manages the non-target floor. Therefore, no particular problem arises even if priority is given to performing update processing on the control unit that manages the target floor.

In the above configuration, it is preferable that in response to a change in a floor route among the plurality of floor routes, the management device updates the floor map information in a first target control unit, which is the control unit that manages the first target floor, then causes the updated floor map information to be transmitted from the first target control unit to a first non-target control unit, which is another one of the control units, and then updates the floor map information in the first non-target control unit, and in response to a change in the connection route, the management device updates the floor map information in second target control units, which are the control units that manage the second target floors, then causes the updated floor map information to be transmitted from at least one of the second target control units to a second non-target control unit, which is another one of the control units, and then updates the floor map information in the second non-target control unit.

According to this configuration, update processing for updating the floor map information in all of the control units can be performed using communication between control units. For example, in the case where the task of updating floor map information in a control unit is performed by a worker, performing the update processing using communication between control units in this way makes it possible to reduce the burden on the worker related to the update task.

The transport system according to the present disclosure need only be able to achieve at least one of the effects described above.

What is claimed is:

1. A transport system in which an article is transported by a transport vehicle, the transport system comprising:
a plurality of floors each having a floor route along which the transport vehicle is configured to travel;
a control device configured to control the transport vehicle; and
a management device configured to manage data updating performed by the control device, and
wherein:
a pair of floors among the plurality of floors are connected to each other by a connection route,
the transport vehicle travels between the pair of floors via the connection route,
the control device holds floor map information regarding the floor route on each of the floors and connection relationship information regarding a connection relationship between the pair of floors connected by the connection route, and controls the transport vehicle on the floor routes and the connection route based on the floor map information and the connection relationship information, and
the management device holds the floor map information regarding the floors in such a manner that a piece of the floor map information can be distinguished for each of the floors, holds the connection relationship information in such a manner that the connection relationship information can be distinguished from the pieces of floor map information corresponding to the floors, and performs update processing for updating the floor map information and the connection relationship information in the control device.

2. The transport system according to claim 1,
wherein in response to a change in a floor route among the plurality of floor routes, the management device updates only the piece of floor map information corresponding to the floor where the changed floor route is provided, and
wherein in response to a change in the connection route, the management device updates the connection relationship information and the pieces of floor map information corresponding to the floors connected to the changed connection route.

3. The transport system according to claim 2,
wherein the management device comprises:
a database configured to have stored therein latest floor map information and latest connection relationship information; and
an update data creation unit configured to create update data to be transmitted to the control device, and
wherein in response to a change in the connection route, the update data creation unit reads, from the database, the connection relationship information and the pieces of floor map information corresponding to the floors connected to the changed connection route, and creates the update data in which new floor map information and new connection relationship information are included.

4. The transport system according to claim 2, wherein:
the control device comprises a plurality of control units,
each of the floors is managed by one or more of the control units,
each of the control units holds the pieces of floor map information corresponding to all of the floors and manages the transport vehicle on each floor managed by the control unit,
in response to a change in a floor route among the plurality of floor routes, the management device prioritizes updating the piece of floor map information corresponding to a first target floor, which is the floor where the changed floor route is provided, in the control unit that manages the first target floor over updating the piece of floor map information corresponding to the first target floor in another one of the control units, and
in response to a change in the connection route, the management device prioritizes updating the pieces of floor map information corresponding to second target floors, which are the floors connected to the changed connection route, in the control units that manage the second target floors over updating the pieces of floor map information corresponding to the second target floors in another one of the control units.

5. The transport system according to claim 4,
wherein in response to a change in a floor route among the plurality of floor routes, the management device updates the floor map information in a first target control unit, which is the control unit that manages the first target floor, then causes the updated floor map information to be transmitted from the first target control unit to a first non-target control unit, which is another one of the control units, and then updates the floor map information in the first non-target control unit, and
wherein in response to a change in the connection route, the management device updates the floor map information in second target control units, which are the control units that manage the second target floors, then causes the updated floor map information to be transmitted from at least one of the second target control units to a second non-target control unit, which is another one of the control units, and then updates the floor map information in the second non-target control unit.
